(19) United States
(12) Patent Application Publication
(10) Pub. No.: US 2012/0206999 A1
(43) Pub. Date: Aug. 16, 2012

(54) CRYSTAL DEVICE, METHOD OF MANUFACTURING CRYSTAL DEVICE, PIEZOELECTRIC VIBRATOR, OSCILLATOR, ELECTRONIC APPARATUS, AND RADIO TIMEPIECE

(76) Inventor: Kiyoshi Aratake, Chiba-shi (JP)

(21) Appl. No.: 13/369,747

(22) Filed: Feb. 9, 2012

(30) Foreign Application Priority Data
Feb. 14, 2011 (JP) 2011-029125

(51) Int. Cl. H01L 41/053; G04C 11/02; H01L 41/22; H03B 5/36

(52) U.S. Cl. 368/47; 310/344; 331/158; 156/150

(57) ABSTRACT

A crystal device includes leading electrodes that are formed on a base substrate, and a bump for mounting a piezoelectric vibrating reed on the leading electrodes, and alignment marks for performing the positioning of the bump are formed on the base substrate separately from the leading electrodes.

### RELATED APPLICATIONS

This application claims priority under 35 U.S.C. §119 to Japanese Patent Application No. 2011-029125 filed on Feb. 14, 2011, the entire content of which is hereby incorporated by reference.

### BACKGROUND OF THE INVENTION

1. Field of the Invention

The present invention relates to a crystal device, a method of manufacturing the crystal device, a piezoelectric vibrator, an oscillator, an electronic apparatus, and a radio timepiece.

2. Description of the Related Art

In recent years, in a mobile phone or a portable information terminal, as a time source, a timing source such as a control signal, a reference signal source or the like, a piezoelectric vibrator (a crystal device) is used which uses crystal or the like. As this kind of piezoelectric vibrator, various piezoelectric vibrators are known, but a surface mount (SMD) type piezoelectric vibrator is known as one of them.

For example, as shown in FIGS. 18 and 19, the piezoelectric vibrator 200 includes a base substrate 201 and a lead substrate 202 formed of a glass material that are anodically bonded to each other via a bonding material 207, and a piezoelectric vibrating reed (a crystal plate) 203 that is hermetically sealed in a cavity C formed between both of the substrates 201 and 202.

The piezoelectric vibrating reed 203 mentioned above is bonded to an electrode pattern 210 formed on a base substrate 201 via a bump 211, and the piezoelectric vibrating reed 203 is electrically bonded to an external electrode 213 formed on a base substrate 201 via a conductive member 212 that is formed so as to penetrate the base substrate 201.

However, as a method of forming the electrode pattern 210 mentioned above, generally, a photolithography technique is used. Specifically, as shown in JP-A-10-284966 and JP-A-2008-219606, after forming an electrode film on the base substrate 201, a resist film is applied so as to cover the electrode film. Moreover, by performing the exposure and the development by the use of a photo mask with a light shielding film formed in a region corresponding to the electrode pattern 210, the resist film is patterned, thereby performing a resist pattern according to an exterior shape of the electrode pattern 201. Moreover, by etching the electrode film by using the resist pattern as a mask, the electrode pattern 201 is formed in which the electrode film other than a region protected by the resist pattern is selectively removed.

### SUMMARY OF THE INVENTION

However, in the method of forming the electrode pattern 201 using the photolithography technique mentioned above, a high-precision electrode pattern 210 can be formed, but there is a problem in that, there are relatively a number of manufacturing requirements such as exposure, development, and etching, which makes it difficult to improve manufacturing efficiency.

Thus, recently, it is considered to adopt a so-called sputtering method of performing the sputtering via a mask material in the formation of the electrode pattern 210. In a masking sputtering method, the sputtering is performed in the state of mounting a mask material (for example, SUS or the like) having an opening portion in a region corresponding to the electrode pattern 210 on a wafer becoming the base substrate 201. As a result, particles of a film forming material which fly out of a target are deposited on the wafer through the opening portion of the mask material, whereby the electrode pattern 210 can be formed.

However, there is a problem in that, when adopting the masking sputtering method mentioned above, for example, the mask material is expanded by heat, flexure is generated, and the particles of the film forming material go around a gap formed between the mask material and the wafer, whereby a blur pattern is easily generated. Particularly, when an area of the wafer is increased, there is a problem in that the amount of flexure is further increased, and the blur pattern is further increased.

Furthermore, in a manufacturing process of a piezoelectric vibrator 200, in order to form a bump 211 on the electrode pattern 210, a part of the electrode pattern 210 is formed as an alignment portion 215 and is patterned in an unique pattern that is absent in other portions. Moreover, a position of the alignment portion 215 is detected by an image recognition or the like, and the alignment of a bump 211 is performed based on the detection result.

However, as mentioned above, when the blur pattern is generated in the electrode pattern 210 by the masking sputtering method as mentioned above, there is a problem in that it is difficult to accurately detect the position of the alignment portion 215, whereby the accuracy of the alignment drops. As a consequence, there is a problem in that the electrode pattern 210 and the bump 211 cause a position deviation.

Thus, the present invention was made in view of the above circumstances, and an object thereof is to provide a crystal device that can accurately position an electrode pattern and a bump by promoting a reduction in the number of manufacturing processes, a method of manufacturing the crystal device, a piezoelectric vibrator, an oscillator, an electronic apparatus, and a radio timepiece.

In order to solve the problem mentioned above and achieve the object, according to an aspect of the present invention, there is provided a crystal device which includes a bonding piece formed by an individualization of a wafer bonding body bonded with a plurality of wafers for each device forming region, and a cavity that is formed in the bonding piece and can seal a crystal plate, wherein the crystal device includes an electrode pattern formed on the device forming region in a first wafer among the plurality of wafers, and a bump for mounting the crystal plate on the electrode pattern, and on the first wafer, an alignment mark for performing the positioning of the bump is formed separately from the electrode pattern.

According to the configuration, by forming the alignment mark separately from the electrode pattern, the position of the alignment mark is easily recognized even in a relatively simple shape, compared to a configuration of the related art in which the alignment mark (the alignment mark 215 mentioned above) is formed integrally with the electrode pattern. That is, for example, in the case of forming the alignment mark by a masking sputtering method, even if somewhat blurred patterns are generated, the alignment mark is easily recognized.

Thus, it is possible to accurately position the bump that is formed based on the position of the alignment mark. As a consequence, it is possible to reliably conduct the crystal plate and the electrode pattern with each other.

Furthermore, the alignment mark may be formed in each of the device forming regions in the first wafer.

According to the configuration, by forming the alignment mark in each of the device forming region in the first wafer, it is possible to perform the more precise positioning corresponding to the electrode patterns of the respective crystal devices.

Furthermore, at least two or more alignment marks may be formed.

According to the configuration, by performing the alignment of the bump based on the positions of the plurality of alignment marks, the more precise positioning can be performed.

Furthermore, according to another aspect of the present invention, there is provided a method of manufacturing a crystal device which includes a bonding piece formed by an individualization of a wafer bonding body bonded with a plurality of wafers for each device forming region, and a cavity that is formed in the bonding piece and can seal a crystal plate, wherein the crystal device includes an electrode pattern formed on the crystal device forming region in a first wafer among the plurality of wafers, and a bump for mounting the crystal plate on the electrode pattern, the method includes an electrode pattern forming process of setting a mask material having a first opening portion in a region corresponding to the electrode pattern on the first wafer and forming the electrode pattern by sputtering; an alignment mark forming process of forming an alignment mark for performing the positioning of the bump on the first wafer separately from the electrode pattern; a bump forming process of forming the bump on the electrode pattern based on a position of the alignment mark; and a mount process of mounting the crystal plate on the electrode pattern via the bump.

According to the configuration, by forming the alignment mark separately from the electrode pattern, the position of the alignment mark is easily recognized even in a relatively simple shape compared to a configuration of the related art in which the alignment mark (the alignment portion 215 mentioned above) is formed integrally with the electrode pattern. That is, when forming the alignment mark by the masking sputtering method, even in a case where a somewhat blurred pattern is generated, the alignment mark is easily recognized.

Thus, in the bump forming process, it is possible to accurately position the bump that is formed based on the position of the alignment mark. Furthermore, it is possible to reduce the number of manufacturing processes and promote an improvement in manufacturing efficiency, compared to a case of forming the electrode pattern by the photolithography technique of the related art.

Furthermore, the mask material may have a second opening portion in a region corresponding to the alignment mark, and the electrode pattern forming process and the alignment mark forming process are performed by the sputtering in the same process.

According to the configuration, by collectively forming the alignment mark and the electrode pattern by the sputtering in the same process, it is possible to easily maintain a relative position between the electrode pattern and the alignment mark. Furthermore, by collectively forming the electrode pattern and the alignment mark, it is possible to promote a reduction in the number of manufacturing processes and promote an improvement in manufacturing efficiency.

In addition, since the mask material for the electrode pattern and the mask material for the alignment mark may be integrally created, a reduction in cost can be promoted.

Furthermore, in the alignment mark forming process, the alignment mark is formed corresponding to each of the device forming regions in the first wafer.

According to the configuration, by forming the alignment marks in each of the device forming regions in the first wafer, the high-precision positioning can be performed corresponding to the electrode patterns of the respective crystal devices.

Furthermore, according to still another aspect of the present invention, there is provided a piezoelectric vibrator in which a piezoelectric vibrating reed as the crystal plate is hermetically sealed in the cavity of the crystal device of the present invention.

According to the configuration, since the crystal device of the present invention is included, it is possible to provide a piezoelectric vibrator that has an excellent conductivity between the piezoelectric vibrating reed hermetically sealed as the crystal plate and the electrode pattern.

Furthermore, according to still another aspect of the present invention, there is provided an oscillator in which the piezoelectric vibrator according to the aspect of the present invention is electrically connected to an integrated circuit as an oscillating element.

Furthermore, according to still another aspect of the present invention, there is provided an electronic apparatus in which the piezoelectric vibrator according to the aspect of the present invention is electrically connected to a count portion.

Furthermore, according to still another aspect of the present invention, there is provided a radio timepiece in which the piezoelectric vibrator according to the aspect of the present invention is electrically connected to a filter portion.

Since the oscillator, the electronic apparatus and the radio timepiece according to the aspect of the present invention include the piezoelectric vibrator according to the aspect of the present invention, it is possible to provide a product having excellent characteristics and reliability.

According to the crystal device, and the method of manufacturing the crystal device according to the aspect of the present invention, it is possible to position the electronic pattern and the bump by promoting a reduction in the number of manufacturing processes.

Furthermore, according to the piezoelectric vibrator according to the aspect of the present invention, it is possible to provide the piezoelectric vibrator which has excellent conductivity between the piezoelectric vibrating reed and the electrode pattern.

Since the oscillator, the electronic apparatus and the radio timepiece according to the aspect of the present invention include the piezoelectric vibrator of the present invention, it is possible to provide a product having excellent characteristics and reliability.

### BRIEF DESCRIPTION OF THE DRAWINGS

FIG. 1 is an exterior perspective view of a piezoelectric vibrator in an embodiment of the present invention.

FIG. 2 is an internal configuration diagram of the piezoelectric vibrator shown in FIG. 1 in which the piezoelectric vibrating reed is viewed from an upper part with a lead substrate detached therefrom.

FIG. 3 is a cross-sectional view of the piezoelectric vibrator along lines A-A shown in FIG. 2.

FIG. 4 is an exploded perspective view of the piezoelectric vibrator shown in FIG. 1.

FIG. 5 is a top view of the piezoelectric vibrating reed.

FIG. 6 is a bottom view of the piezoelectric vibrating reed.

FIG. 7 is a flowchart that shows a method of manufacturing the piezoelectric vibrator.

FIG. 8 is a process diagram for describing the method of manufacturing the piezoelectric vibrator and an exploded perspective view of a wafer bonding body.

FIG. 9 is a diagram that shows a state in which a plurality of penetration holes is formed in a base substrate wafer becoming a source of the base substrate.

FIG. 10 is a perspective view of a metal pin.

FIG. 11 is a diagram that shows a state in which a leading electrode is patterned on a first surface of the base substrate wafer.

FIG. 12 is a diagram (1) that describes a patterning method of the leading electrode.

FIG. 13 is a diagram (2) that describes a patterning method of the leading electrode.

FIG. 14 is a diagram (3) that describes a patterning method of the leading electrode.

FIG. 15 is a configuration diagram of an oscillator that shows an embodiment of the present invention.

FIG. 16 is a configuration diagram of an electronic apparatus that shows an embodiment of the present invention.

FIG. 17 is a configuration diagram of a radio timepiece that shows an embodiment of the present invention.

FIG. 18 is an internal structural diagram of a piezoelectric vibrator of the related art in which the piezoelectric vibrating reed is viewed from the upper part with the lead substrate detached therefrom.

FIG. 19 is a cross-sectional view of the piezoelectric vibrator of the related art.

### DETAILED DESCRIPTION OF THE PREFERRED EMBODIMENTS

Hereinafter, an embodiment of the present invention will be described based on the drawings.

### (Piezoelectric Vibrator)

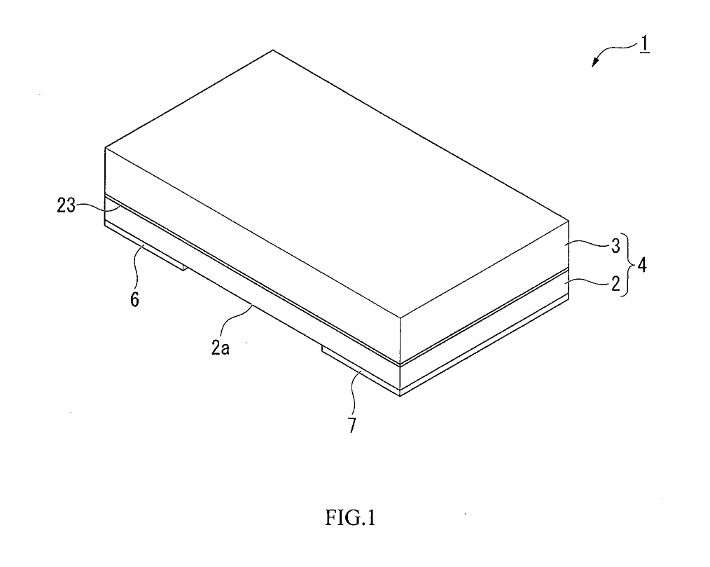

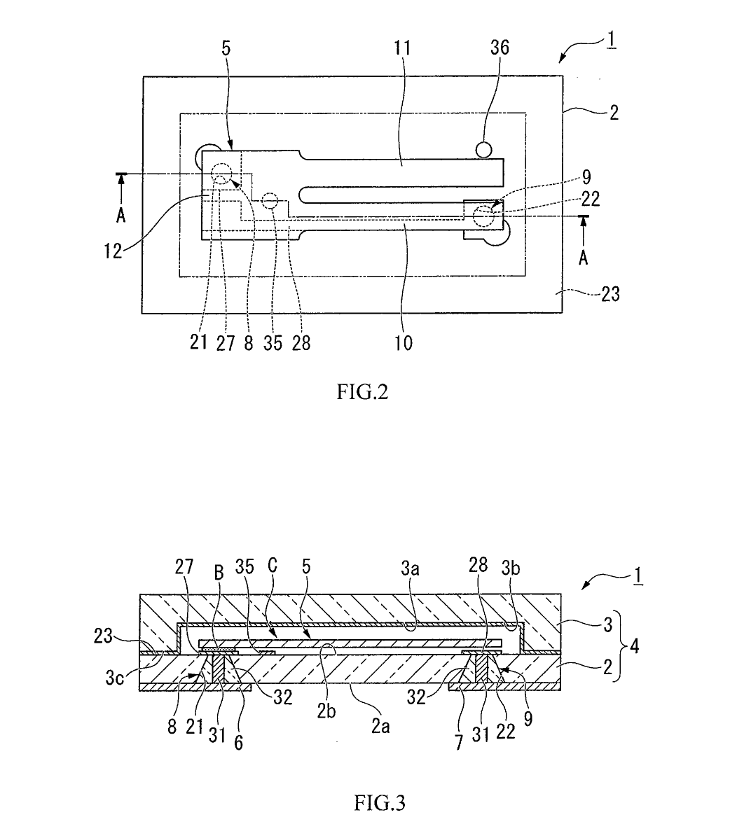

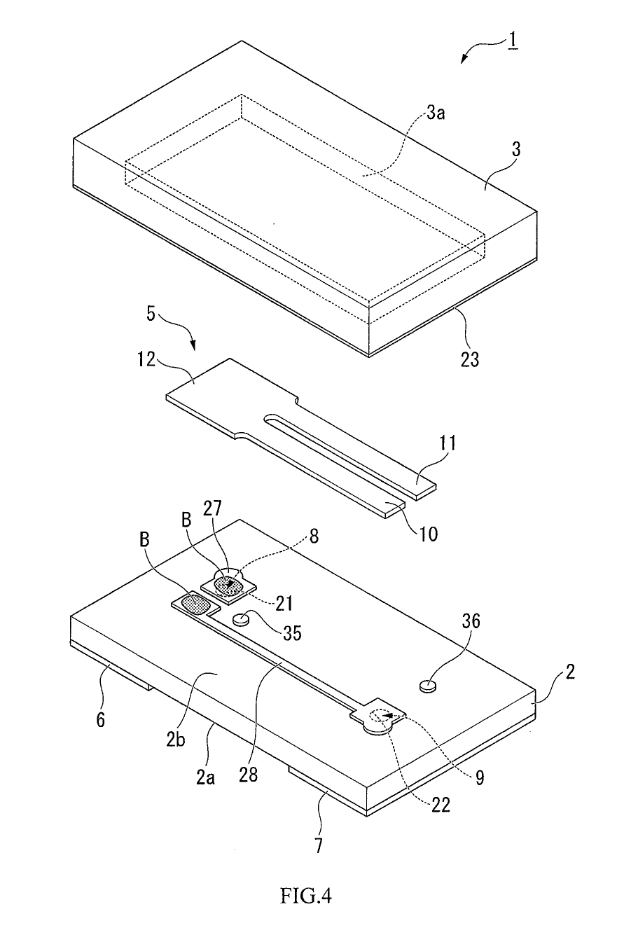

FIG. 1 is an exterior perspective view in which a piezoelectric vibrator in the present embodiment is viewed from a lead substrate side. Furthermore, FIG. 2 is an internal configuration diagram of the piezoelectric vibrator in which the piezoelectric vibrating reed is viewed from the upper part with the lead substrate detached therefrom. Furthermore, FIG. 3 is a cross-sectional view of the piezoelectric vibrator take along lines A-A shown in FIG. 2, and FIG. 4 is an exploded perspective view of the piezoelectric vibrator. In addition, in FIGS. 2 to 4, in order to clarify the drawings, an excitation electrode 15, drawing electrodes 19 and 20, mount electrodes 16 and 17, and weight metal film 24 of a piezoelectric vibrating reed 5 described later are omitted.

As shown in FIGS. 1 to 4, a piezoelectric vibrator (a crystal device) 1 of the present embodiment is a surface mount type piezoelectric vibrator 1 which includes a box-shaped package (a bonding piece) 4 in which a base substrate 2 and a lead substrate 3 are anodically bonded to each other via a bonding material 23, and the piezoelectric vibrating reed (a crystal plate) 5 that is received in a cavity C of the package 4. Moreover, the piezoelectric vibrating reed 5 and external electrodes 6 and 7 provided on a back surface 2a (a lower surface of FIG. 3) of the base substrate 2 are electrically connected to each other by a pair of penetration electrodes 8 and 9 that penetrate through the base substrate 2.

The base substrate 2 is a transparent insulation substrate formed of a glass material, for example, a soda-lime glass, and is formed in a plate shape. In the base substrate 2, a pair of penetration holes 21 and 22 formed with a pair of penetration electrodes 8 and 9 is formed. The penetration holes 21 and 22 have cross sections of a taper shape in which diameters thereof are gradually reduced from the back surface 2a of the base substrate 2 toward an upper surface 2b (an upper surface of FIG. 3).

Like the base substrate 2, the lead substrate 3 is a transparent insulation substrate formed of a glass material, for example, a soda-lime glass, and is formed in a plate shape that has a size capable of being superimposed on the base substrate 2. Moreover, at an inner surface 3b (a lower surface of FIG. 3) side of the lead substrate 3, a concave portion 3a of a rectangular shape is formed in which the piezoelectric vibrating reed 5 is accommodated. The concave portion 3a forms the cavity C that accommodates the piezoelectric vibrating reed 5 when the base substrate 2 and the lead substrate 3 are superimposed on each other. Moreover, the lead substrate 3 is anodically bonded to the base substrate 2 via the bonding material 23 in the state of opposing the concave portion 3a to the base substrate 2 side. That is, the inner surface 3b side of the lead substrate 3 constitutes the concave portion 3a formed in a central portion and a frame region 3c that is formed around the concave portion 3a and becomes a bonding surface with the base substrate 2.

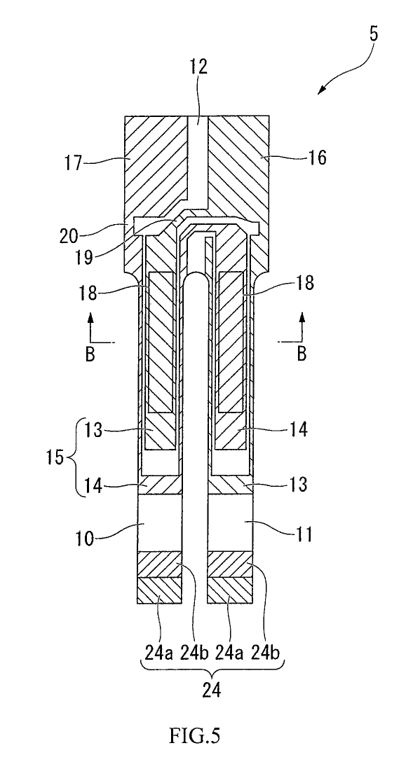

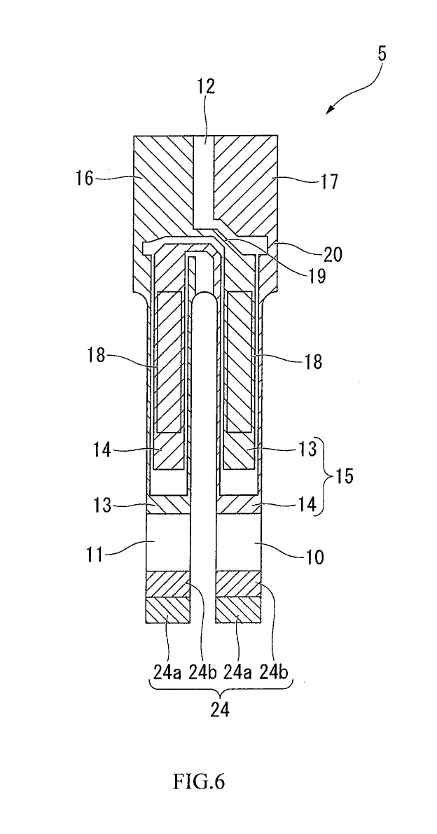

FIG. 5 is a plan view in which the piezoelectric vibrating reed is viewed from the upper surface, and FIG. 6 is a plan view in which the piezoelectric vibrating reed is viewed from the lower surface.

The piezoelectric vibrating reed 5 is a tuning-fork type vibrating reed formed of crystal as a piezoelectric material, and is vibrated when a predetermined voltage is applied.

The piezoelectric vibrating reed 5 has a pair of vibration arm portions 10 and 11 disposed in parallel, and a base portion 12 that integrally fixes proximal end sides of the pair of vibration arm portions 10 and 11, an excitation electrode 15 that is constituted by a first excitation electrode 13 and a second excitation electrode 14 which are formed on the outer surfaces of the pair of vibration arm portions 10 and 11 and vibrate the pair of vibration arm portions 10 and 11, and mount electrodes 16 and 17 that are electrically connected to the first excitation electrode 13 and the second excitation electrode 14.

Furthermore, the piezoelectric vibrating reed 5 includes groove portions 18, which are formed along a longitudinal direction of the vibration arm portions 10 and 11, respectively, on both main surfaces of the pair of vibration arm portions 10 and 11. The groove portions 18 are formed so as to reach a portion near approximately the middle from the proximal end sides of the vibration arm portions 10 and 11.

The excitation electrode 15 constituted by the first excitation electrode 13 and the second excitation electrode 14 is an electrode that vibrates the pair of vibration arm portions 10 and 11 in a direction approaching or separated from each other at a predetermined frequency, and is patterned and formed on the outer surfaces of the pair of vibration arm portions 10 and 11 in the state of being electrically separated, respectively. Specifically, the first excitation electrode 13 is mainly formed on the groove portions 18 of one vibration arm portions 10 and on both side surfaces of the other vibration arm portions 11. Furthermore, the second excitation electrode 14 is mainly formed on both side surfaces of one vibration arm portion 10 and on the groove portion 18 of the other vibration arm portion 11.

In addition, the first excitation electrode 13 and the second excitation electrode 14 are electrically connected to the mount electrodes 16 and 17 via the drawing electrodes 19 and 20 on both main surfaces of the base portion 12, respectively. The piezoelectric vibrating reed 5 is applied with the voltage via the mount electrodes 16 and 17.

In addition, the excitation electrode 15, the mount electrodes 16 and 17, and the drawing electrodes 19 and 20 mentioned above are formed by, for example, a conductive coating such as chrome (Cr), nickel (Ni), aluminum (Al) or titanium (Ti).

Furthermore, the tips of the pair of vibration arm portions 10 and 11 are coated with a weight metal film 24 for performing the adjustment (the frequency adjustment) so that the vibration state thereof is vibrated in a predetermined frequency range. In addition, the weight metal film 24 is divided into a rough adjustment film 24a that is used when roughly adjusting the frequency and a minute adjustment film 24b used when minutely adjusting the frequency. By performing the frequency adjustment by the use of the rough adjustment film 24a and the minute adjustment film 24b, it is possible to put the frequencies of the pair of vibration arm portions 10 and 11 within the scope of a nominal frequency of the device.

As shown in FIGS. 2 and 3, the piezoelectric vibrating reed 5 configured in this manner is bump-bonded onto leading electrodes 27 and 28 formed on the surface 2b of the base substrate 2 by the use of a bump B such as gold. More specifically, the first excitation electrode 13 of the piezoelectric vibrating reed 5 is bump-bonded onto one leading electrode 27 via one mount electrode 16 and the bump B, and the second excitation electrode 14 of the piezoelectric vibrating reed 5 is bump-bonded onto the other leading electrode 28 via the other mount electrode 17 and the bump B. As a result, the piezoelectric vibrating reed 5 is supported in the state of floating from the upper surface 2b of the base substrate 2, and the respective mount electrodes 16 and 17 and the leading electrodes 27 and 28 are electrically connected to each other, respectively.

Furthermore, as shown in FIGS. 2 to 4, on the upper surface 2b of the base substrate 2, a plurality (for example, two) alignment marks 35 and 36 for performing the alignment of the bump B in a manufacturing process of a piezoelectric vibrator 1 described later are located adjacent to the leading electrodes 27 and 28 mentioned above. The alignment marks 35 and 36 form relatively a simple shape such as circular shape or a rectangular shape (the circular shape in the present embodiment) when viewed from a plan, and are formed by the same material in the same process as the leading electrodes 27 and 28. Specifically, among the respective alignment marks 35 and 36, one alignment mark 35 is located in a position overlapping with the base portion 12 of the piezoelectric vibrating reed 5 near the leading electrode 27, and the other alignment mark 36 is located in a position not overlapping with the vibration arm portion 11 at the tip side of the vibration arm portion 11.

The external electrodes 6 and 7 are provided at both sides on the back surface 2a of the base substrate 2 in the longitudinal direction, and are electrically connected to the piezoelectric vibrating reed 5 via the respective penetration electrodes 8 and 9 and the leading electrodes 27 and 28. More specifically, one external electrode 6 is electrically connected to one mount electrode 16 of the piezoelectric vibrating reed 5 via one penetration electrode 8 and one leading electrode 27. Furthermore, the other external electrode 7 is electrically connected to the other mount electrode 17 of the piezoelectric vibrating reed 5 via the other penetration electrode 9 and the other leading electrode 27.

The penetration electrodes 8 and 9 are formed by a barrel 32 integrally fixed to the penetration holes 21 and 22 by the burning, and a core portion 31. The respective penetration electrodes 8 and 9 play a role in completely blocking the penetration holes 21 and 22 to maintain the air-tightness in the cavity C and conducting external electrodes 6 and 7 and the leading electrodes 27 and 28. Specifically, one penetration electrode 8 is situated below the leading electrode 27 between the external electrode 6 and the base portion 12, and the other penetration electrode 9 is situated below the leading electrode 28 between the external electrode 7 and vibration arm portion 10.

The barrel 32 is formed by the burning of a pasty glass frit. The barrel 32 has flat both ends and is formed in a cylindrical shape having approximately the same thickness as the base substrate 2. Moreover, in the center of the barrel 32, the core portion 31 is disposed so as to penetrate the center hole of the barrel 32. Additionally, in the present embodiment, according to the shapes of the penetration holes 21 and 22, the exterior of the barrel 32 is formed in a conical shape (taper-shaped cross section). Moreover, the barrel 32 is burned in the state of being buried in the penetration holes 21 and 22, whereby the barrel 32 is firmly fixed to the penetration holes 21 and 22.

The core portion 31 mentioned above is a conductive core formed in a columnar shape by a metallic material, is flat at both ends like the barrel 32, and is formed so as to have approximately the same thickness as that of the base substrate 2. In addition, when the penetration electrodes 8 and 9 are formed as finished products as described above, the core portion 31 is formed in a columnar shape so as to have approximately the same thickness as that of the base substrate 2. However, in the manufacturing course, as shown in FIG. 10 described below, the core portion 31 forms a tack-shaped metal pin 37 together with a base portion 38 of the flat plate shape connected to one end portion of the core portion 31.

On the whole inner surface 3b of the lead substrate 3, a bonding material 23 for the anodic bonding is formed. Specifically, the bonding material 23 is formed over the whole inner surface of the frame region 3c and the concave portion 3a. The bonding material 23 of the present embodiment is formed of Si film, but it is also possible to form the bonding material 23 by Al. Furthermore, it is also possible to use a Si bulk material having a low resistance by the doping or the like as the bonding material. Moreover, as described later, the bonding material 23 and the base substrate 2 are anodically bonded to each other, and the cavity C are vacuum-sealed.

When operating the piezoelectric vibrator 1 configured in this manner, a predetermined driving voltage is applied to the external electrodes 6 and 7 formed on the base substrate 2. As a result, it is possible to cause the electric current to flow in the excitation electrode 15 of the piezoelectric vibrating reed 5, whereby the piezoelectric vibrator 1 can be vibrated at a predetermined frequency in a direction bringing the pair of vibration arm portions 10 and 11 closer to each other or separating them from each other. Moreover, the vibration of the pair of vibration arm portions 10 and 11 can be used as a time source, a timing source of a control signal, a reference signal source or the like.

### (Method of Manufacturing Piezoelectric Vibrator)

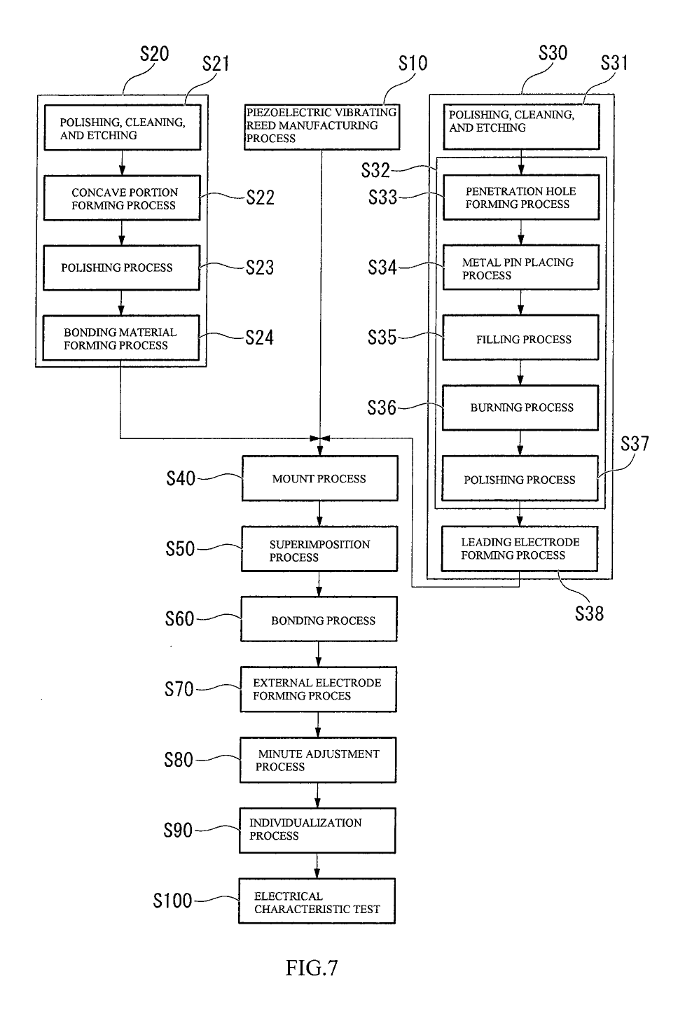

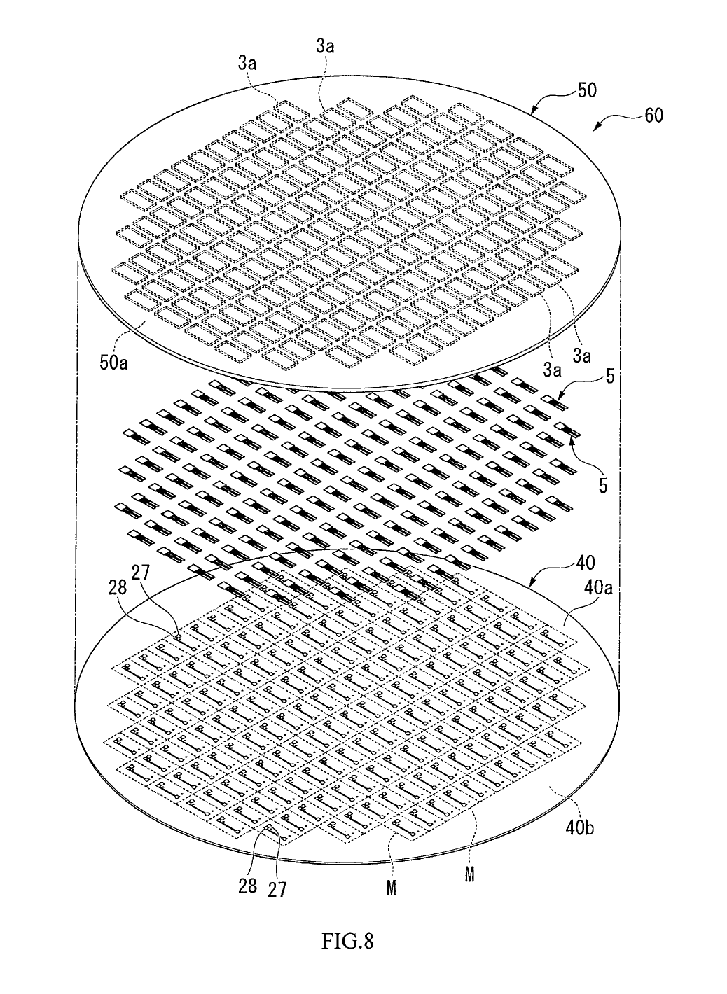

Next, a method of manufacturing the piezoelectric vibrator mentioned above will be described. FIG. 7 is a flowchart that shows a method of manufacturing the piezoelectric vibrator according to the present embodiment. FIG. 8 is an exploded perspective view of a wafer bonding body. Hereinafter, a method will be described in which a plurality of piezoelectric vibrating reeds 5 is sealed between the base substrate wafer (a first wafer) 40 with a plurality of base substrates 2 extended thereon and the lead substrate wafer (a wafer) 50 with the plurality of lead substrates 3 extended thereon to form a wafer bonding body 60, and a plurality of piezoelectric vibrators 1 is concurrently manufactured by cutting the wafer bonding body 60 for each of the forming regions (device forming regions) of the piezoelectric vibrator 1. In addition, a dashed-line M shown in FIG. 8 shows a cutting line that is cut in the cutting process.

As shown in FIG. 7, the method of manufacturing the piezoelectric vibrator according to the present embodiment mainly has a piezoelectric vibrating reed production process (S10), a lead substrate wafer production process (S20), a base substrate wafer production process (S30), and an assembling process (after S40). Among them, it is possible to perform the piezoelectric vibrating reed production process (S10), the lead substrate wafer production process (S20), and the base substrate wafer production process (S30) in parallel.

Firstly, the piezoelectric vibrating reed production process is performed to produce the piezoelectric vibrating reed 5 as shown in FIGS. 5 and 6 (S10). Specifically, a Lambert ore of crystal is sliced at a predetermined angle to form a wafer of a predetermined thickness. Next, after the wafer is wrapped and roughed, a damaged layer is removed by etching, and then the wafer is formed to have a predetermined thickness by performing a specular working such as polishing. Next, after performing a suitable process such as wafer cleaning, the wafer is patterned to an exterior shape of the piezoelectric vibrating reed 5 by the photolithography technique, and the film formation and the patterning of the metal film are performed, thereby forming the excitation electrode 15, the drawing electrodes 19 and 20, the mount electrode 16 and 17, and the weight metal film 24. As a result, a plurality of piezoelectric vibrating reeds 5 can be manufactured.

Furthermore, after manufacturing the piezoelectric vibrating reed 5, the rough adjustment of the resonance frequency is performed. This is performed by irradiating the rough adjustment film 24a of the weight metal film 24 with laser light to evaporate a part thereof and changing the weight. In addition, a minute adjustment, which accurately adjusts the resonance frequency, is performed after the mounting.

### (Lead Substrate Wafer Production Process)

Next, as shown in FIGS. 7 and 8, a lead substrate wafer production process is performed which manufactures the lead substrate wafer 50 becoming the lead substrate 3 later up to the state of immediately before performing the anodic bonding (S20). Specifically, after the soda-lime glass is polished up to a predetermined thickness and is cleaned, a disk-like lead substrate wafer 50 is formed in which the damaged layer of the top surface thereof is removed by the etching or the like (S21). Next, a concave portion forming process is performed which forms a plurality of concave portions 3a for the cavity C on a first surface 50a (a lower surface in FIG. 8) of the lead substrate wafer 50 in a matrix direction by etching or the like (S22).

Next, in order to ensure air permeability between the lead substrate wafer 50 and a base substrate wafer 40 described later, a polishing process (S23) is performed which at least polishes the first surface 50a side of the lead substrate wafer 50 becoming the bonding surface with the base substrate wafer 40, thereby performing the specular working of the first surface 50a.

Next, a bonding material forming process (S24) is performed which forms the bonding material 23 on the whole (the bonding surface between the lead substrate wafer 50 and the base substrate wafer 40, and the inner surface of the concave portion 3a) of the first surface 50a of the lead substrate wafer 50. In this manner, by forming the bonding material 23 on the whole of the first surface 50a of the lead substrate wafer 50, the patterning of the bonding material 23 is unnecessary, whereby the manufacturing cost can be reduced. In addition, the forming of the bonding material 23 can be performed by the film forming method such as sputtering or a CVD. Furthermore, since the bonding surface is polished before the bonding material forming process (S24), the flatness of the surface of the bonding material 23 is ensured, whereby it is possible to realize the stable bonding with the base substrate wafer 40.

In this manner, the lead substrate wafer production process (S20) is finished.

(Base Substrate Wafer production Process)

Next, a base substrate wafer production process is performed which manufactures the base substrate wafer 40 becoming the base substrate 2 later up to the state of immediately before performing the anodic bonding (S30) at the same timing as the process mentioned above or before and after that. Firstly, after the soda-lime glass is polished up to a predetermined thickness and is cleaned, the disc-like base substrate wafer 40 is formed in which the damaged layer of the top surface thereof is removed by etching or the like (S31).

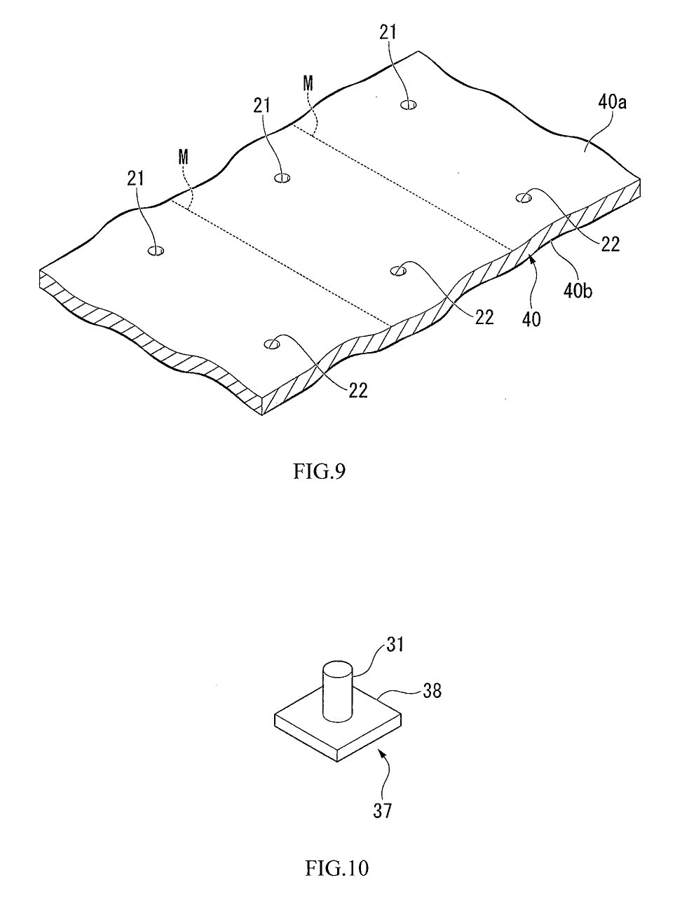

Next, a penetration electrode forming process (S32) is performed which forms penetration electrodes 8 and 9 (see FIG. 3) that penetrate through the base substrate wafer 40 in the thickness direction and conduct the inside of the cavity C with the outside of the piezoelectric vibrator 1. Hereinafter, the penetration electrode forming process (S32) will specifically be described. FIG. 9 is a perspective view that shows the state of forming a plurality of penetration holes in the base substrate wafer.

Firstly, as shown in FIG. 7, in the penetration electrode forming process (S32), a penetration hole forming process (S33) is formed which forms a plurality of pairs of penetration holes 21 and 22 penetrating the base substrate wafer 40. Specifically, after forming the concave portion from the second surface 40b of the base substrate wafer 40 by the press working or the like, by performing the polishing at least from the first surface 40a side of the base substrate wafer 40, it is possible to penetrate the concave portion to form the penetration holes 21 and 22.

Next, a metal pin placing process (S34) is performed which places the core portion 31 of the metal pin in the plurality of penetration holes 21 and 22 formed in the penetration hole forming process (S33). FIG. 10 is a perspective view of the metal pin.

As shown in FIG. 10, the metal pin 37 has a flat plate-shaped base portion 38, and a core portion 31 which is formed to have a length that is slightly shorter than the thickness of the base substrate wafer 40 along a direction approximately perpendicular to the surface of the base portion 38 on the base surface 38, and in which the tip is evenly formed.

Moreover, the core portion 31 of the metal pin 37 is inserted from the first surface 40a of the base substrate wafer 40 into the penetration holes 21 and 22. At this time, until the surface of the base portion 38 of the metal pin 37 comes into contact with the first surface 40a of the base substrate wafer 40, the core portion 31 is inserted. Herein, there is a need to place the metal pin 37 so that an axial direction of the core portion 31 approximately coincides with the axial direction of the penetration holes 21 and 22. However, since the metal pin 37 formed with the core portion 31 on the base portion 38 is used, by a simple operation of merely pressing the base portion 38 until being brought into contact with the base substrate wafer 40, the axial direction of the core portion 31 can approximately coincide with the axial direction of the penetration holes 21 and 22. Thus, it is possible to improve operability in the metal pin placing process (S34).

Next, a filling process (S35) is performed which transports the base substrate wafer 40 with the metal pin 37 set thereon into a vacuum printing device and fills the pasty glass frit in the penetration holes 21 and 22. As a result, between the penetration holes 21 and 22 and the metal pin 37, a glass frit is filled without a gap.

After that, a burning process (S36) is performed which burns the glass frit filled in the penetration holes 21 and 22 at a predetermined temperature. As a result, the penetration holes 21 and 22, the glass frit buried in the penetration holes 21 and 22, and the metal pin 37 (the core portion 31) placed in the glass frit are fixed to each other. When performing the burning, in order to burn each base portion 38, in the state of approximately matching the axial direction of the core portion 31 with the axial direction of the penetration holes 21 and 22, both of them can be integrally fixed to each other. When the glass frit is burned, it is solidified as a barrel 32.

Next, a polishing process of polishing and removing the base portion 38 of the metal pin 37 is performed (S37). As a result, it is possible to remove the base portion 38 which played a role in positioning the barrel 32 and the core portion 31, whereby only the core portion 31 can remain inside the barrel 32. Furthermore, simultaneously, the second surface 40b of the base substrate wafer 40 is polished to become a flat surface. Moreover, the polishing is performed until the tip of the core portion 31 is exposed. As a consequence, it is possible to obtain a plurality of penetration electrodes 8 and 9 in which the barrel 32 and the core portion 31 are integrally fixed to each other.

In this case, the first surface 40a and the second surface 40b of the base substrate wafer 40 are approximately the same surface as those of both ends of the barrel 32 and the core portion 31. That is, the first surface 40a and the second surface 40b of the base substrate wafer 40 can be approximately the same surface as the surface of the penetration electrodes 8 and 9. In addition, at the point of time when performing the polishing process (S37), the penetration electrode forming process (S32) is finished.

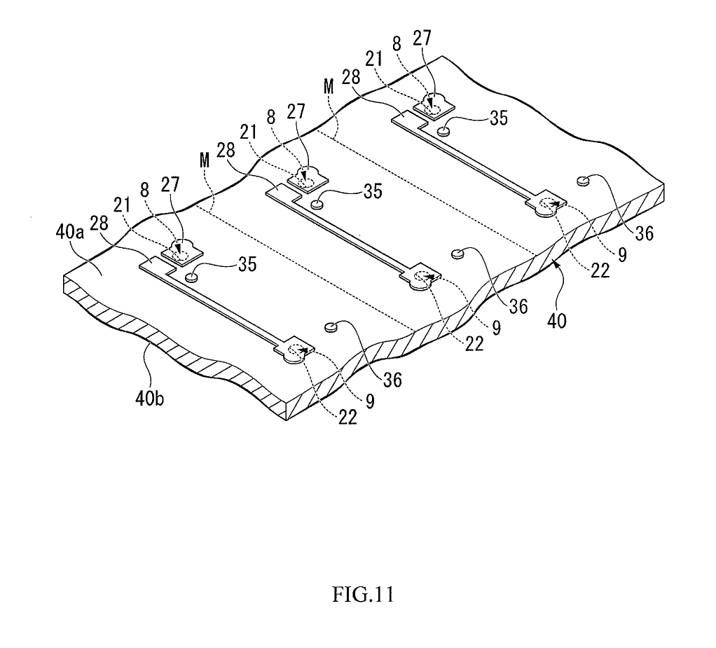

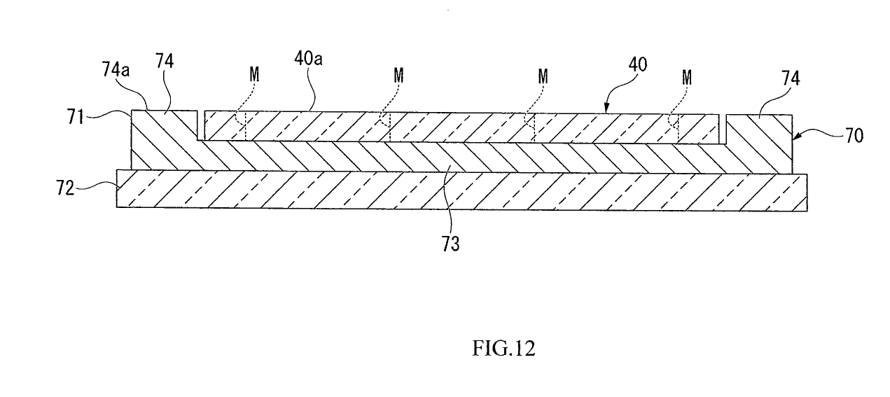

FIG. 11 is a perspective view that shows the state of patterning the leading electrode on the first surface of the base substrate wafer.

Next, as shown in FIG. 11, a leading electrode forming process is performed which forms the leading electrodes 27 and 28 formed of a conductive film on the first surface 40a of the base substrate wafer 40 (S38: an electrode pattern forming process and an alignment mark forming process). In this manner, the base substrate wafer production process (S30) is finished.

### (Leading Electrode Forming Process)

Herein, the leading electrode forming process (S38) mentioned above will be described. FIGS. 12 to 14 are diagrams that show a patterning method of the leading electrode.

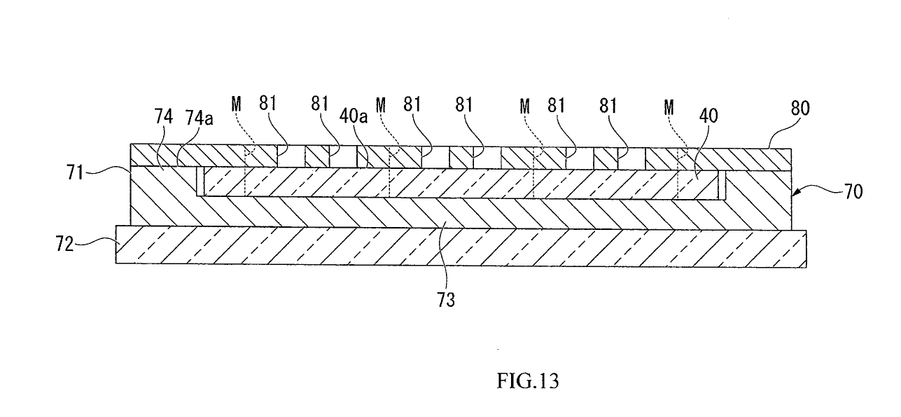

The leading electrodes 27 and 28 are performed by performing the masking sputtering on the first surface 40a of the base substrate wafer 40. Specifically, as shown in FIG. 12, the base substrate wafer 40 is mounted on a substrate supporting jig 70 so that the base substrate wafer 40 is moved in a sputtering device. The substrate supporting jig 70 includes a base plate 71 that mounts the base substrate wafer 40, and a magnet plate 72 that is able to support and fix a mask material 80 (see FIG. 13) formed of a magnetic substance by magnetic force. The base plate 71 includes a plane portion 73 that has a size capable of mounting the base substrate wafer 40, and a periphery portion 74 that constitutes a periphery of the plane portion 73. The periphery portion 74 is formed to be thicker than the plane portion 73. That is, a region with the base substrate wafer 40 mounted thereon is in a concave state. Moreover, the thickness of the base substrate wafer 40 is approximately identical to the height (the thickness) of the periphery portion 74, and in the state in which the base substrate wafer 40 is mounted on the plane portion 73, the first surface 40a of the base substrate wafer 40 is approximately the same surface as the surface 74a of the periphery portion 74.

Next, as shown in FIG. 13, the mask material 80 is mounted so as to cover the periphery portion 74 of the base substrate wafer 40 and the base plate 71. The mask material 80 is formed so that an external form thereof is approximately the same as that of the base plate 71 when viewed from the plane. Furthermore, since the mask material 80 is formed by, for example, a plate material having a thickness of about 100 μm formed of a magnetic substance such as SUS, the mask material 80 is supported and fixed by the magnetic plate 72.

In the mask material 80, a plurality of opening portions (a first opening portion and a second opening portion) 81 corresponding to the shapes of the leading electrodes 27 and 28 and the alignment marks 35 and 36 mentioned above are formed corresponding to the forming regions of the respective base substrates 2, respectively. The mask material 80 of the present embodiment is configured so that a thickness of a portion, where the opening portion 81 is not formed, is regular. That is, the mask material 80 is configured merely by forming the opening portion 81 in the plate-shaped member having the regular thickness.

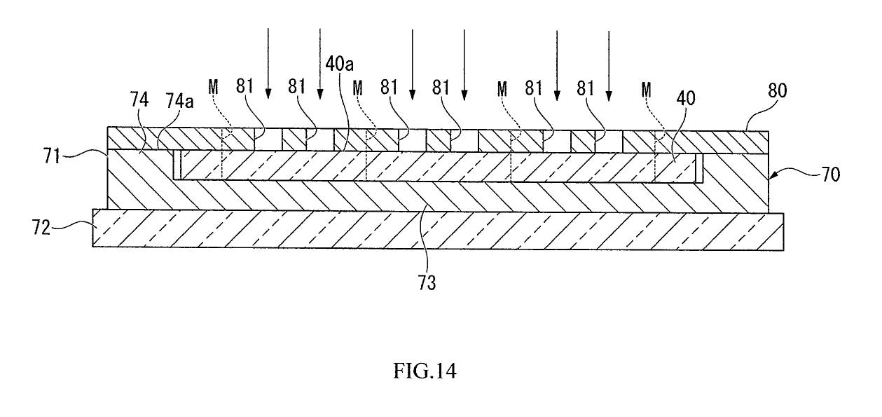

Next, as shown in FIG. 14, in the state in which the mask material 80 is supported and fixed, the substrate supporting jig 70 is moved into a sputtering device (not shown) to perform the sputtering. As a result, the particles of the film forming material which fly from the target are deposited on the first surface 40a of the base substrate wafer 40 through the opening portion 81, whereby the leading electrodes 27 and 28 and the alignment marks 35 and 36 are formed on the first surface 40a of the base substrate wafer 40. At this time, by collectively forming the leading electrodes 27 and 28 and the alignment marks 35 and 36 in the same process, it is possible to simply maintain the relative position between the leading electrodes 27 and 28 and the alignment marks 35 and 36.

In addition, the penetration electrodes 8 and 9 are approximately the same surface as the first surface 40a of the base substrate wafer 40 as mentioned above. For that reason, the leading electrodes 27 and 28 patterned on the first surface 40a of the base substrate wafer 40 are formed in the state of coming into close-contact with the penetration electrodes 8 and 9 without generating a gap or the like therebetween. As a result, it is possible to reliably perform the conduction between one leading electrode 27 and one penetration electrode 8 and the conduction between the other leading electrode 28 and the other penetration electrode 9.

### (Assembling Process)

Next, the piezoelectric vibrating reeds 5 created in the piezoelectric vibrating reed production process (S10) are mounted on the respective leading electrodes 27 and 28 of the base substrate wafer 40 created by the base substrate wafer production process (S30) via the bump B such as gold, respectively (S40). Specifically, firstly, the positions (the central positions) of the alignment marks 35 and 36 by the image recognition or the like are detected, and bump forming positions on the leading electrodes 27 and 28 are calculated based on the detection result. Moreover, in the bump forming positions on the leading electrodes 27 and 28, the bumps B are formed by the use of a gold wire, respectively (a bump forming process).

Moreover, after mounting the base portion 12 of the piezoelectric vibrating reed 5 on the bump B, the mount electrodes 16 and 17 of the piezoelectric vibrating reed 5 are pressed against the bump B while heating the bump B to a predetermined temperature. As a result, the piezoelectric vibrating reed 5 is mechanically supported by the bump B, and the mount electrodes 16 and 17 are electrically connected to the leading electrodes 27 and 28.

Next, a superimposition process is performed (S50) which superimposes the base substrate wafer 40 and the lead substrate wafer 50 created by the production process of the respective wafers 40 and 50 mentioned above. Specifically, both of the wafers 40 and 50 are aligned in a correct position while setting a standard mark (not shown) or the like as an indicator. As a result, the mounted piezoelectric vibrating reed 5 is received in the cavity C that is surrounded by the concave portion 3a formed in the lead substrate wafer 50 and the base substrate wafer 40.

After the superimposition process (S50), a bonding process is performed which applies a predetermined voltage at a predetermined temperature atmosphere to perform the anodic bonding in the state of putting the two superimposed wafers 40 and 50 into an anodic bonding device (not shown) and clamping outer peripheral portions of the wafers 40 and 50 by a holding mechanism (not shown) (S60). Specifically, a predetermined voltage is applied between the bonding material 23 and the lead substrate wafer 50. Then, an electrochemical reaction occurs in an interface between the bonding material 23 and the lead substrate wafer 50, and both of them are firmly brought into close-contact with each other and are anodically bonded to each other. As a result, the piezoelectric vibrating reed 5 can be sealed in the cavity C, whereby it is possible to obtain a wafer bonding body 60 in which the base substrate wafer 40 is bonded to the lead substrate wafer 50. Moreover, by anodically bonding both of the wafers 40 and 50 like the present embodiment, a time degradation, a deviation due to an impact or the like, the bending of the wafer bonding body 60 or the like are prevented, whereby both of the wafers 40 and 50 can further be bonded firmly, compared to a case of bonding both of the wafers 40 and 50 by an adhesive or the like.

Moreover, after the anodic bonding mentioned above is finished, an external electrode forming process is performed which patterns the conductive material on the second surface 40b of the base substrate wafer 40 and forms a plurality of pairs of external electrodes 6 and 7 that is electrically connected to the pair of penetration electrodes 8 and 9, respectively (S70). By the process, the piezoelectric vibrating reed 5 sealed in the cavity C can be operated by the use of the external electrodes 6 and 7.

Next, in the state of the wafer bonding body 60, a minute adjustment process of minutely adjusting the frequencies of the individual piezoelectric vibrating reeds 5 sealed in the cavity C to enter a predetermined range is performed (S80). Specifically, the voltage is applied to the pair of external electrodes 6 and 7 formed on the second surface 40b of the base substrate wafer 40 to vibrate the piezoelectric vibrating reed 5. Moreover, laser light is irradiated from the outside through the lead substrate wafer 50 while measuring the frequency, thereby evaporating the minute adjustment film 24b of the weight metal film 24. As a result, since the weights of the tip sides of the pair of vibration arm portions 10 and 11 are changed, the frequency of the piezoelectric vibrating reed 5 can be minutely adjusted so as to enter a predetermined range of the nominal frequency. At this time, the alignment marks 35 and 36 of the present embodiment are formed in the position where they are not superimposed on the vibration arm portions 10 and 11, and the alignment marks 35 and 36 do not interfere with laser light.

Moreover, an individualizing process (S90) of cutting the bonded wafer bonding body 60 along the cutting line M (the forming region of the piezoelectric vibrator 1) is performed.

After that, an internal electrical characteristic test is performed (S100). Specifically, the resonance frequency, the resonance resistance value, the drive level characteristic (an excitation electric power dependence of the resonance frequency and the resonance resistance value) of the piezoelectric vibrator 1 or the like are measured and checked. Furthermore, an insulation resistance characteristics or the like are also checked. Finally, an exterior test of the piezoelectric vibrator 1 is performed, and the size, the quality or the like is finally checked.

Thereby, the piezoelectric vibrator 1 is completed.

In this manner, in the present embodiment, a configuration was adopted in which the leading electrodes 27 and 28 are formed on the base substrate 2 by the masking sputtering method, and the alignment marks 35 and 36 for performing the alignment of the bump B separately from the leading electrodes 27 and 28 are formed.

According to the configuration, by forming the alignment marks 35 and 36 separately from the leading electrodes 27 and 28, the positions (the central positions) of the alignment marks 35 and 36 are easily recognized even in a relatively simple shape, compared to the configuration of the related art in which the alignment mark (the alignment portion 215) is integrally formed with the leading electrodes 27 and 28.

That is, when forming the alignment marks 35 and 36 by the masking sputtering method, even if somewhat blurred patterns are generated, the alignment marks 35 and 36 are easily recognized.

Thus, it is possible to accurately position the bump B that is formed based on the positions of the alignment marks 35 and 36. As a consequence, it is possible to reliably conduct the piezoelectric vibrating reed 5 with the leading electrodes 27 and 28. Furthermore, compared to the case of forming the leading electrodes 27 and 28 by the photolithography technique of the related art, the number of manufacturing process can be reduced to promote an improvement in manufacturing efficiency.

In addition, by performing the alignment of the bump B based on the positions of the plurality (two in the present embodiment) of alignment marks 35 and 36, the high-precision positioning can be performed.

Herein, in the leading electrode forming process (S38), by collectively forming the alignment marks 35 and 36 and the leading electrodes 27 and 28 by the same material and in the same process, it is possible to easily maintain the relative position between the leading electrodes 27 and 28 and the alignment marks 35 and 36. Furthermore, by collectively forming the leading electrodes 27 and 28 and the alignment marks 35 and 36, a reduction in number of the manufacturing process is promoted, and an improvement in manufacturing efficiency can be promoted.

In addition, since the mask materials for the leading electrodes 27 and 28 and the mask materials for the alignment marks 35 and 36 may be integrally created, a reduction in cost can be promoted.

Furthermore, by forming the alignment marks 35 and 36 in each of the forming regions of the base substrate 2 in the base substrate wafer 40, it is possible to perform the high-precision positioning corresponding to the leading electrodes 27 and 28 of the respective base substrates 2.

In addition, by forming the shapes of the alignment marks 35 and 36 when viewed from the plane as circular shapes, it is possible to easily calculate the central position from the outlines of the alignment marks 35 and 36.

Moreover, in the present embodiment, since the package 4 mentioned above is included, it is possible to provide the reliable piezoelectric vibrator 1 that has the excellent conductivity with the piezoelectric vibrating reed 5 and the leading electrodes 27 and 28.

### (Oscillator)

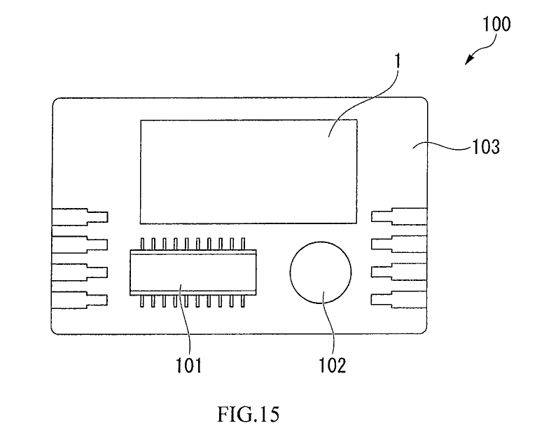

Next, an embodiment of an oscillator according to the present invention will be described with reference to FIG. 15.

As shown in FIG. 15, the oscillator 100 of the present embodiment is configured as an oscillating element in which the piezoelectric vibrator 1 is electrically connected to an integrated circuit 101. The oscillator 100 includes a substrate 103 with an electronic component 102 such as a condenser mounted thereon. The integrated circuit 101 for the oscillator mentioned above is mounted on the substrate 103, and the piezoelectric vibrating reed 5 of the piezoelectric vibrator 1 is mounted near the integrated circuit 101. The electronic component 102, the integrated circuit 101, and the piezoelectric vibrator 1 are electrically connected by a wiring pattern (not shown). In addition, the respective components are molded by resin (not shown).

In the oscillator 100 configured in this manner, upon applying the voltage to the piezoelectric vibrator 1, the piezoelectric vibrating reed 5 in the piezoelectric vibrator 1 is vibrated. The vibration is converted to the electric signal by the piezoelectric characteristic of the piezoelectric vibrating reed 5 and is input to the integrated circuit 101 as the electric signal. The input electric signal is subjected to various processes by the integrated circuit 101 and is output as the frequency signal. As a result, the piezoelectric vibrator 1 functions as the oscillating element.

Furthermore, by selectively setting the configuration of the integrated circuit 101, for example, a RTC (real time clock) module or the like depending on the demand, it is possible to add a function of controlling an operation date or a time of the device or external device other than a single-function oscillator for the timepiece or the like, or providing a time, a calendar or the like.

As mentioned above, according to the oscillator 100 of the present embodiment, since the piezoelectric vibrator 1 mentioned above is included, it is possible to provide the oscillator 100 having excellent characteristics and reliability. Furthermore, in addition to this, it is possible to obtain a high precision frequency signal that is stable for a long period of time.

(Electronic apparatus)

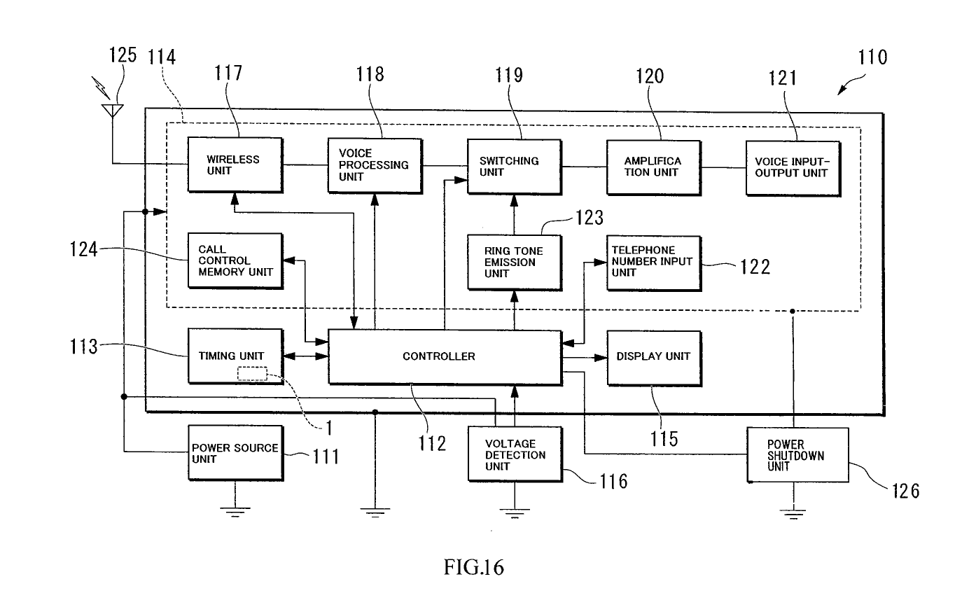

Next, an embodiment of the electronic apparatus according to the present invention will be described with reference to FIG. 16. Furthermore, as the electronic apparatus, a portable information device 110 having the piezoelectric vibrator 1 mentioned above will be described as an example. Firstly, the portable information device 110 of the present embodiment is represented by, for example, a mobile phone, and is a device that develops and improves a wristwatch in the related art. An exterior thereof is similar to the wristwatch, a liquid crystal display is disposed in a portion corresponding to a text plate, and a current time or the like can be displayed on the screen. Furthermore, in the case of being used as a communicator, the device is removed from the wrist, and communication like the mobile phone of the related art can be performed by a speaker and a microphone equipped in the inner portion of the band. However, the device is considerably reduced in size and weight compared to the mobile phone of the related art.

### (Portable Information Device)

Next, a configuration of portable information device 110 of the present embodiment will be described. As shown in FIG. 16, the portable information device 110 includes the piezoelectric vibrator 1 and a power source portion 111 for supplying the electric power. For example, the power source portion 111 is formed of a lithium secondary battery. A control portion 112 performing various controls, a count portion 113 performing the count such as the time, a communication portion 114 performing the communication with the outside, a display portion 115 displaying various pieces of information, and a voltage detection portion 116 detecting the voltage of the respective function portions are connected to the power source portion 111 in parallel. Moreover, the electric power is supplied to the respective function portions by the power source portion 111.

The control portion 112 controls the respective function portions, and performs the operation control of the whole system such as the reception and transmission of voice data, the measurement and display of the current time or the like. Furthermore, the control portion 112 includes a ROM with a program written thereon in advance, a CPU reading and executing the program written on the ROM, a RAM used as a work area of the CPU or the like.

The count portion 113 includes an integrated circuit equipped with an oscillation circuit, a register circuit, a counter circuit, an interface circuit or the like, and the piezoelectric vibrator 1. When applying the voltage to the piezoelectric vibrator 1, the piezoelectric vibrating reed 5 is vibrated, and the vibration is converted into the electric signal by the piezoelectric characteristic of crystal and is input to the oscillation circuit as the electric signal. The output of the oscillation circuit is binarized and is counted by the register circuit and the counter circuit. Moreover, the signal is received from and transmitted to the control portion 112 via the interface circuit, and the current time, the current date, the calendar information or the like are displayed on the display portion 115.

The communication portion 114 has the same function as the mobile phone of the related art, and includes a wireless portion 117, a voice process portion 118, a switching portion 119, an amplification portion 120, a voice input and output portion 121, a phone number input portion 122, a ringtone generating portion 123, and a call control memory portion 124.

The wireless portion 117 exchanges the transmission and the reception of various pieces of data such as the voice data with a base station via an antenna 125. The voice process portion 118 encodes and decodes the voice signal that is input from the wireless portion 117 or the amplification portion 120. The amplification portion 120 amplifies the signal, which is input from the voice process portion 118 or the voice input and output portion 121, up to a predetermined level. The voice input and output portion 121 is constituted by a speaker, a microphone or the like, heightens the ringtone or the received voice or collects the voice.

Furthermore, the ringtone generating portion 123 creates the ringtone depending on the call from the base station. The switching portion 119 switches the amplification portion 120 connected to the voice process portion 118 into the ringtone generating portion 123 only at the time of the reception, whereby the ringtone created in the ringtone generating portion 123 is output to the voice input and output portion 121 via the amplification portion 120.

In addition, the call control memory portion 124 stores the program relating to the call arrival and departure control of the communication. Furthermore, the phone number input portion 122 includes, for example, number keys from 0 to 9, and other keys, and a phone number or the like of a communication target is input by pressing the number keys or the like.

When the voltage added to the respective function portions such as the control portion 112 by the power source portion 111 is lower than a predetermined value, the voltage detection portion 116 detects the voltage drop and notifies the same to the control portion 112. The predetermined voltage value of this time is a value which is set as a minimum voltage required for stably operating the communication portion 114 in advance, and is, for example, about 3V. The control portion 112 received the notification of the voltage drop from the voltage detection portion 116 prevents the operation of the wireless portion 117, the voice process portion 118, the switching portion 119, and the ringtone generating portion 123. Particularly, the operation stop of the wireless portion 117 having high power consumption is essential. In addition, an indication, in which the communication portion 114 is unusable from the shortage of the battery residual amount, is displayed on the display portion 115.

That is, the operation of the communication portion 114 is prohibited by the voltage detection portion 116 and the control portion 112, and the indication thereof can be displayed on the display portion 115. The display may be a text message, but an X (false) mark may be displayed on a phone icon displayed on the upper portion of the display surface of the display portion 115 as a further intuitive display.

In addition, a power source cutting portion 126 capable of selectively cutting the power source of a portion relating to the function of the communication portion 114 is included, whereby the function of the communication portion 114 can further reliably be stopped.

As mentioned above, according to the portable information device 110 of the present embodiment, since the piezoelectric vibrator 1 mentioned above is included, it is possible to provide the portable information device 110 having excellent characteristics and reliability. Furthermore, in addition to this, the high-precision timepiece information stable for a long period of time can be displayed.

### (Radio Timepiece)

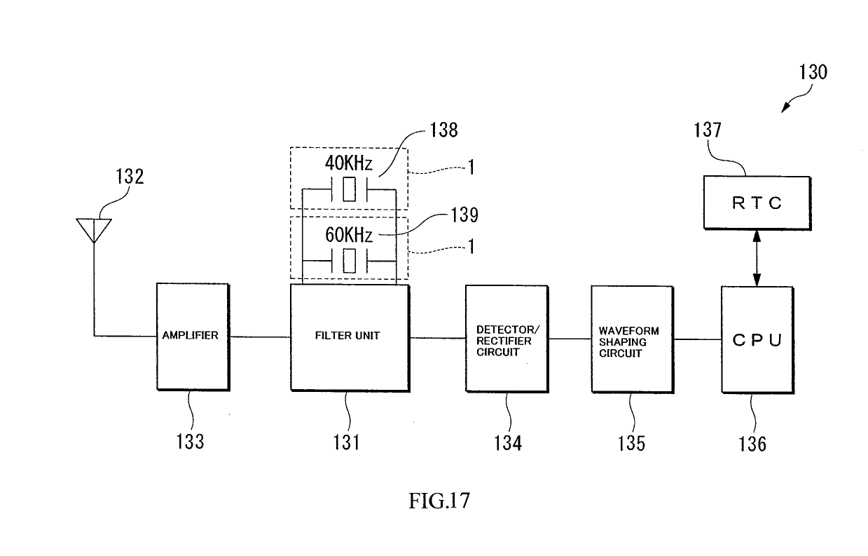

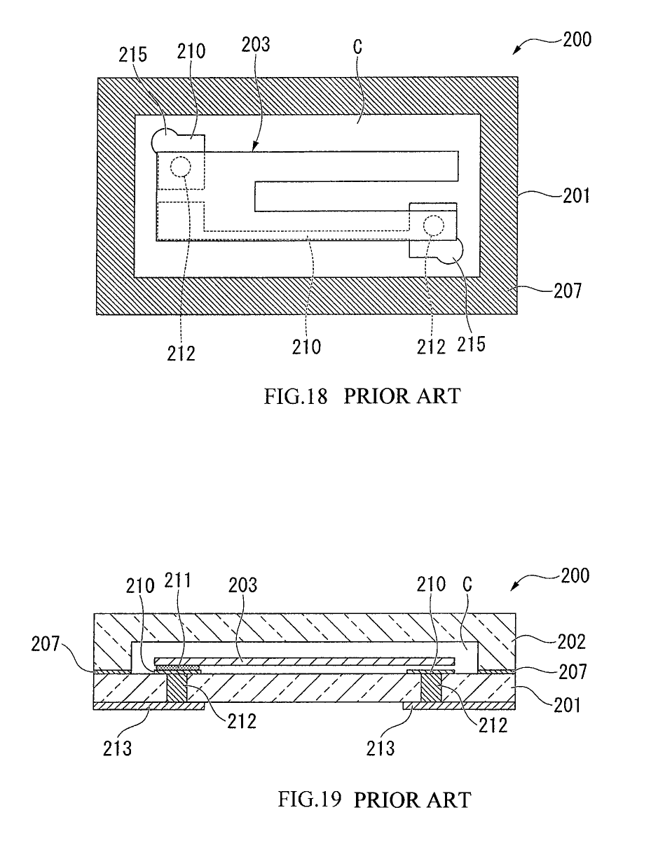

Next, an embodiment of a radio timepiece according to the present invention will be described with reference to FIG. 17.

As shown in FIG. 17, the radio timepiece 130 of the present embodiment includes the piezoelectric vibrator 1 electrically connected to a filter portion 131, and is a timepiece that has a function of receiving a standard radio wave which includes the timepiece information and automatically correcting and displaying the same at the correct time.

In Japan, in Fukushima-ken (40 kHz) and Saga-ken (60 kHz), transmission stations (transmission departments) transmitting the standard radio waves are present and transmit the standard radio wave, respectively. Long waves such as 40 kHz and 60 kHz combined has a nature of being diffused through the surface of earth and a nature of being diffused while being reflected by an ionization layer and the surface of earth, the diffusion range is wide, and two transmission stations cover all Japan.

Hereinafter, a functional configuration of the radio timepiece 130 will specifically be described.

The antenna 132 receives the standard radio wave having the long wave of 40 kHz or 60 kHz. The standard radio wave of the long wave performs an AM modulation of time information called a time code to the carrier wave of 40 kHz or 60 KHz. The received standard radio wave of the long wave is amplified by an amplifier 133, and is filtered and tuned by a filter portion 131 having a plurality of piezoelectric vibrators 1. The piezoelectric vibrator 1 in the present embodiment includes crystal vibrator portions 138 and 139 having the same resonance frequency of 40 kHz and 60 kHz as the carrier frequency mentioned above, respectively.

In addition, the filtered signal of a predetermined frequency is detected and demodulated by a detection and rectifier circuit 134. Next, the time code is taken out via a waveform shaping circuit 135 and is counted by the CPU 136. In the CPU 136, information such as current year, integration date, day of the week, and time are read. The read information is reflected on the RTC 137 and the correct time information is displayed.

Since the carrier wave is 40 kHz or 60 kHz, as the crystal vibration portions 138 and 139, a vibrator having the tuning fork-like structure mentioned above is preferable.

In addition, the description mentioned above is indicated as an example in Japan, but the frequency of the standard radio waves of the long waves differs abroad. For example, a standard radio wave of 77.5 kHz is used in Germany. Thus, when the radio timepiece 130 capable of responding even abroad is built in the portable device, there is a need for the piezoelectric vibrator 1 having a frequency difference from the case of Japan.

As mentioned above, according to the radio timepiece 130 of the present embodiment, since the piezoelectric vibrator 1 mentioned above is included, it is possible to provide a radio timepiece 130 of high quality having excellent characteristics and reliability. Furthermore, in addition to this, it is possible to stably and accurately count the time for a long period of time.

In addition, the technical scope of the present invention is not limited to the embodiment mentioned above, but various modifications can be added within the scope without departing from the gist of the present invention.

For example, in the embodiment mentioned above, the piezoelectric vibrating reed is sealed within the package and the piezoelectric vibrator is manufactured while using the method of manufacturing the package according to the present invention. However, it is also possible to manufacture a device other than the piezoelectric vibrator by sealing a crystal plate other than the piezoelectric vibrating reed within the package.

Furthermore, in the embodiment mentioned above, the method of manufacturing the package of the present invention was described as an example of the piezoelectric vibrator which uses the tuning-fork type piezoelectric vibrating reed. However, for example, the present invention may be applied to the piezoelectric vibrator using an AT cut type piezoelectric vibrating reed (a thickness shear vibrating reed) or the like, without being limited thereto.

Furthermore, in the embodiment mentioned above, a case was described where the metal pin 37 erected from the base portion 38 is placed in the penetration holes 21 and 22, and then the base portion 38 is polished and removed, thereby forming the penetration electrodes 7 and 8, but the present invention is not limited thereto. For example, the penetration holes 21 and 22 may be formed as a concave portion having a bottom, the metal pin of the cylindrical shape may be placed in the concave portion, whereby the penetration electrode may be formed. However, the present embodiment is advantageous in that the metal pin can be placed in the penetration hole without leaning.

In addition, in the embodiment mentioned above, a case was described where the alignment marks 35 and 36 are formed in the positions corresponding to the respective base substrate 2 in the base substrate wafer 40, respectively, in the manufacturing process of the piezoelectric vibrator 1, but the present invention is not limited thereto. That is, the alignment marks may be formed in an arbitrary position in the base substrate wafer 40. In this case, the alignment marks may be formed at the outside of the forming region of the base substrate 2 in the base substrate wafer 40.

Furthermore, the shapes of the alignment marks 35 and 36 are not limited to a rectangular shape or a circular shape, but can suitably be changed to a cross shape or the like.

In addition, the leading electrodes 27 and 28 and the alignment marks 35 and 36 may be formed in separate processes.

What is claimed is:

1. A crystal device comprising:
a bonding piece formed by an individualization of a wafer bonding body bonded with a plurality of wafers for each device forming region; and
a cavity that is formed in the bonding piece and can seal a crystal plate,
wherein the crystal device includes
an electrode pattern that is formed on the device forming region in a first wafer among the plurality of wafers; and
a bump for mounting the crystal plate on the electrode pattern, and
an alignment mark for performing the positioning of the bump is formed on the first wafer separately from the electrode pattern.

2. The crystal device according to claim 1,
wherein the alignment mark is formed in each of the device forming regions in the first wafer.

3. The crystal device according to claim 1,
wherein at least two or more alignment marks are formed.

4. A method of manufacturing a crystal device which includes
a bonding piece formed by an individualization of a wafer bonding body bonded with a plurality of wafers for each device forming region, and
a cavity that is formed in the bonding piece and can seal a crystal plate,
the crystal device including
an electrode pattern that is formed on the crystal device forming region in a first wafer among the plurality of wafers; and
a bump for mounting the crystal plate on the electrode pattern,
wherein the method comprising:
an electrode pattern forming process of setting a mask material having a first opening portion in a region corresponding to the electrode pattern on the first wafer, and forming the electrode pattern by sputtering;
an alignment mark forming process of forming an alignment mark for performing the positioning of the bump on the first wafer separately from the electrode pattern;
a bump forming process of forming the bump on the electrode pattern based on a position of the alignment mark; and
a mount process of mounting the crystal plate on the electrode pattern via the bump.

5. The method according to claim 4,
wherein the mask material has a second opening portion in a region corresponding to the alignment mark, and
the electrode pattern forming process and the alignment mark forming process are performed by the sputtering in the same process.

6. The method according to claim 4,
wherein, in the alignment mark forming process, the alignment marks are formed corresponding to each of the device forming regions in the first wafer.

7. A piezoelectric vibrator in which a piezoelectric vibrating reed as the crystal plate is hermetically sealed in the cavity of the crystal device according to claim 1.

8. An oscillator in which the piezoelectric vibrator according to claim 7 is electrically connected to an integrated circuit as an oscillating element.

9. An electronic apparatus in which the piezoelectric vibrator according to claim 7 is electrically connected to a count portion.

10. A radio timepiece in which the piezoelectric vibrator according to claim 7 is electrically connected to a filter portion.
